(19) United States
(12) Patent Application Publication
(10) Pub. No.: US 2012/0098014 A1
(43) Pub. Date: Apr. 26, 2012

(54) SEMICONDUCTOR LIGHT EMITTING DEVICE

(75) Inventor: Eiji MURAMOTO, Kanagawa-Ken (JP)

(73) Assignee: Kabushiki Kaisha Toshiba, Tokyo (JP)

(21) Appl. No.: 13/281,305

(22) Filed: Oct. 25, 2011

(30) Foreign Application Priority Data
Oct. 26, 2010 (JP) P2010-239642

(51) Int. Cl. H01L 33/42

(52) U.S. Cl. 257/98; 257/E33.064

(57) ABSTRACT

According to one embodiment, a semiconductor light-emitting device includes a semiconductor layer with a multi-layer structure including an active layer, and having a first surface and a second surface opposite to the first surface, a plurality of ITO pillars formed on the second surface of the semiconductor layer, the second surface being exposed partially, a metal layer formed on the second surface of the semiconductor layer, the metal layer filling a space between the adjacent ITO pillars and covers the ITO pillars, wherein the second surface of the semiconductor layer is exposed from the space between the adjacent ITO pillars, and the metal layer is formed on the exposed second surface.

### CROSS REFERENCE TO RELATED APPLICATION

This application is based upon and claims the benefit of priority from Japanese Patent Application No. 2010-239642, filed on Oct. 26, 2010, the entire contents of which are incorporated herein by reference.

### BACKGROUND

An existing nitride semiconductor light-emitting device includes a reflective electrode formed in a p type gallium nitride (GaN) layer, and is configured so that light beams emitted from a light-emitting layer are extracted from an n type GaN layer side either directly or after being reflected by the reflective electrode.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a sectional view illustrating the semiconductor light-emitting device of this embodiment.

FIG. 2 is a plan view illustrating ITO pillars exposed when a semiconductor layer is removed from a semiconductor light-emitting device.

FIGS. 3A to 4C are sectional views sequentially illustrating main portions of steps of manufacturing the semiconductor light-emitting device 10.

FIGS. 5A to 5C show diagrams illustrating the etching characteristics of the ITO film 30.

FIG. 6 is a sectional view illustrating a semiconductor light-emitting device where the light-extraction structure is formed in the n type GaN layer 14.

FIG. 7 is a sectional view illustrating a flip-chip semiconductor light-emitting device.

FIGS. 8A to 8D show sectional views sequentially illustrating main portions of steps for manufacturing a semiconductor light-emitting device of this embodiment.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

According to one embodiment, a semiconductor light-emitting device includes a semiconductor layer with a multi-layer structure including an active layer, and having a first surface and a second surface opposite to the first surface, a plurality of ITO pillars formed on the second surface of the semiconductor layer, the second surface being exposed partially, a metal layer formed on the second surface of the semiconductor layer, the metal layer filling a space between the adjacent ITO pillars and covers the ITO pillars, wherein the second surface of the semiconductor layer is exposed from the space between the adjacent ITO pillars, and the metal layer is formed on the exposed second surface.

### First Embodiment

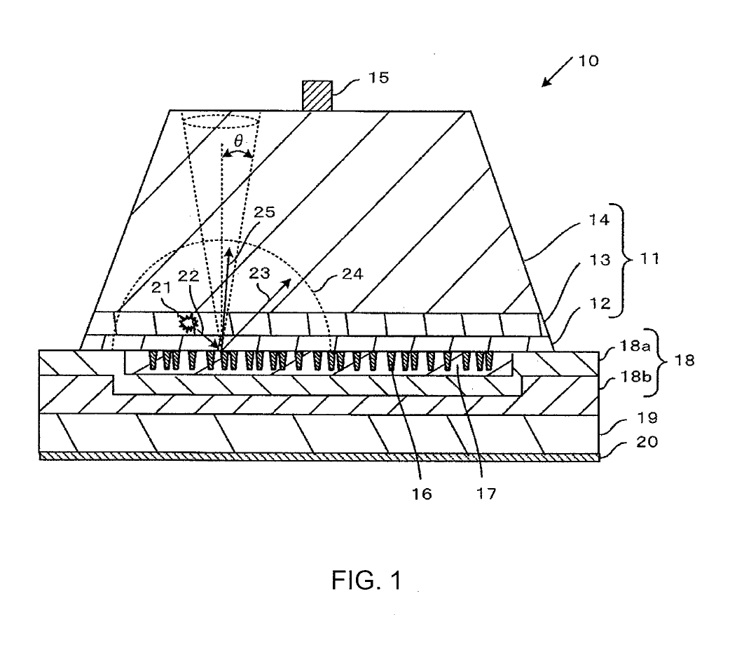

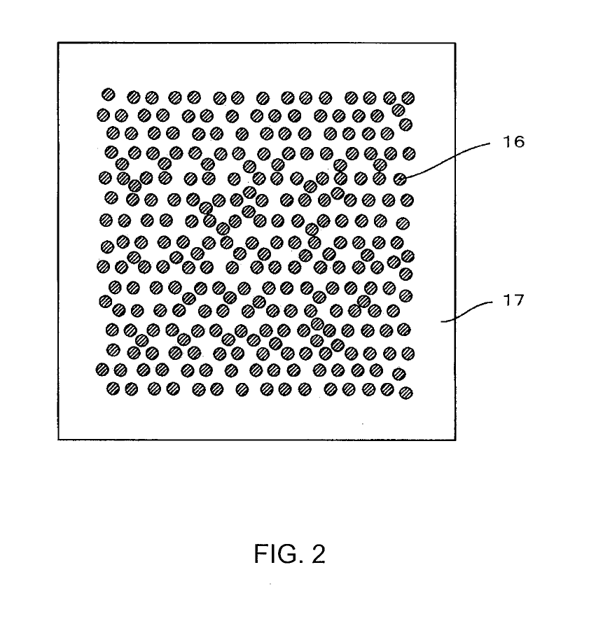

A semiconductor light-emitting device of this embodiment is described by referring to FIGS. 1 and 2. FIG. 1 is a sectional view illustrating the semiconductor light-emitting device of this embodiment. FIG. 2 is a plan view illustrating ITO pillars exposed when a semiconductor layer is removed from a semiconductor light-emitting device.

As shown in FIG. 1, in a semiconductor light-emitting device 10 of this embodiment, a semiconductor layer 11 has a multi-layer structure including a p type GaN layer 12, an active layer 13, and an n type GaN layer 14.

The active layer 13 includes an n type GaN clad layer with a thickness of approximately 2 μm, a multiple quantum well (MQW) layer, and a p type GaN clad layer with a thickness of approximately 100 nm, for example. In the MQW layer, a GaN barrier layer with a thickness of 5 nm and an InGaN well layer with a thickness of 2.5 nm are alternately stacked on each other with the InGaN well layer placed on top.

The p type GaN layer 12 is formed thinly, for example with a thickness of 10 nm, on a p type GaN clad layer, and is provided as a contact layer. The n type GaN layer 14 is formed thickly, for example with a thickness of approximately 3 μm, and is provided as an underlying monocrystal layer used to form the active layer 13 and the p type GaN layer 12.

The composition ratio x of indium (In) to the InGaN well layer (i.e., InxGa1-xN layer, 0<x<1) is set at approximately 0.1 so that the light extracted from the semiconductor layer 11 can have a peak wavelength, for example, of approximately 450 nm.

The side surfaces of the semiconductor layer 11 slopes in a way that the distance between the side surfaces gradually increases from the top of the n type GaN layer 14 towards the bottom of the p type GaN layer 12. The purpose of this is to enhance the light extraction efficiency of the light beams incident on the side surfaces of the semiconductor layer 11.

A first electrode (N electrode) 15 is a laminate film including, for example, a layer of titanium (Ti), a layer of platinum (Pt) and a layer of gold (Au). The first electrode 15 is formed on a surface (first surface) of the n type GaN layer 14 of the semiconductor layer 11.

Multiple ITO (indium tin oxide) pillars 16 are formed on a surface (second surface) of the p type GaN layer 12 of the semiconductor layer 11 in a dispersed way that makes the surface of the p type GaN layer 12 exposed partially. The ITO pillars 16 are projections formed on the surface of the p type GaN layer 12. The multiple ITO pillars 16 as shown in FIG. 1 are formed on the surface of the p type GaN layer 12.

FIG. 2 is a plan view illustrating how the multiple ITO pillars 16 are dispersedly formed on the surface of the p type GaN layer 12 in the way that makes parts of the surface exposed.

Each ITO pillar 16 is made of crystalline ITO with a height of approximately 100 nm, with a width of approximately 100 nm to 500 nm, and with a density of approximately 10 to 50 pillars per square micrometer (μm2), for example. The ITO pillars 16 are provided in order to function as scattering members for scattering light beams 22 traveling toward the reflective electrode 17 out of light beams 21 emitted from the active layer 13.

The reflective electrode 17 is formed on the surface of the p type GaN layer 12 of the semiconductor layer 11 in such a way as to be filled into spaces among adjacent ITO pillars 16 and to cover the ITO pillars 16. The reflective electrode 17 is provided in order to reflect light beams, which have not been scattered by the ITO pillars 16, to the semiconductor layer 11, and in order to establish an ohmic contact with the p type GaN layer 12.

Silver (Ag) or an alloy of silver is suitable for the reflective electrode 17 because such materials have high light reflectance and guarantee a favorable level of the ohmic contact between the reflective electrode 17 and the p type GaN layer 12. As a cap layer, either a nickel (Ni) layer, a platinum layer (Pt) or a rhodium (Rh) layer may be formed on top of a Ag electrode. Silver-indium (Agin) alloy, silver-palladium-copper (APC: AgPdCu) alloy and the like are suitable as the silver alloy. A Ag-based reflective electrode has a better ohmic contact characteristic and better adhesiveness, if the Ag-based reflective electrode is subjected to heat treatment in an atmosphere containing both nitrogen and oxygen. A preferred temperature range for the heat treatment is not lower than 300° C. but not higher than 500° C., approximately.

A bonding metal layer 18 is formed from a first bonding metal layer 18a and a second bonding metal layer 18b. The first bonding metal layer 18a is a laminate film including, for example, a layer of titanium (Ti), a layer of platinum (Pt) and a layer of gold (Au). The first bonding metal layer 18a is formed on the surface of the p type GaN layer of the semiconductor layer 11 so that the first bonding metal layer 18a can cover the reflective electrode 17. The second bonding metal layer 18b is made, for example, of a solder material such as gold-tin (AuSn) alloys.

Though details are to be described later, the first bonding metal layer 18a formed on the surface of the p type GaN layer 12 and the second bonding metal layer 18b formed on a support substrate 19 are subjected to thermal compression bonding. Thereby, the semiconductor layer 11 and the support substrate 19 are bonded together to form a single unified body.

The support substrate 19 is either a semiconductor substrate or a metal substrate, which is good at electrical conductivity and thermal conductivity. Silicon (Si), germanium (Ge), a copper-tungsten (CuW) alloy, a copper-molybdenum (CuMo) alloy and the like are suitable for the support substrate 19. Note that the support substrate 19 does not have to be transparent to the light beams 21 emitted from the active layer 13.

A second electrode 20 is formed to provide an ohmic contact if the support substrate 19 is made of silicon (Si) or germanium (Ge). The second electrode 20 is made, for example, of titanium (Ti) or aluminum (Al). If the support substrate 19 is made of the CuW alloy or the CuMo alloy, the second electrode 20 is unnecessary because the support substrate 19 per se serves as an ohmic electrode.

The semiconductor light-emitting device 10 has a constitution which enhances the light extraction efficiency of the light beams 21 emitted from the active layer 13 by increasing the proportion of light beams incident on the top and side surfaces of the n type GaN layer 14 at an incidence angle not greater than the critical angle θ (=approximately 24°) for an interface between the GaN surface and the air, in a way that the light beams 22 traveling toward the reflective electrode 17 are scattered in all directions by use of the ITO pillars 16.

If no ITO pillars 16 serving as light scattering members existed, the light beams 22 traveling towards the reflective electrode 17, out of the light beams 21 emitted from the active layer 13, would be reflected regularly by the reflective electrode 17. Out of the light beams reflected regularly by the reflective electrode 17, light beams 23 incident on the top surface of the n type GaN layer 14 at a greater incidence angle than the critical angle θ would be totally reflected in a repetitive manner inside the n type GaN layer 14, and would be gradually absorbed and disappear eventually. As a consequence, the light beams 23 could not be extracted from the semiconductor layer 11.

If, in contrast, the ITO pillars 16 serving as light scattering members exist, the light beams 22 can be scattered stochastically in any light scattering direction 24 at an angle in a range of 0° to 180° which is marked with a broken line. Hence, because the amount of light beams 25 incident on the top surface of the n type GaN layer 14 at a smaller incidence angle than the critical angle θ increases, the light extraction efficiency can be enhanced.

In the phenomenon of light scattering, a size parameter α is determined by the wavelength of light and the dimension of scattering particles, and expressed with α=π·D/λ, where D is the diameter of the scattering particles and λ is the wavelength of the light. A phenomenon of light scattering can be represented depending upon the size parameter α. When α is sufficiently smaller than 1 (α<<1), the Rayleigh scattering is applicable to the light scattering phenomenon. When α is substantially equal to 1 (α≈1), the Mie scattering is applicable to the light scattering phenomenon. When a that is sufficiently larger than 1 (α>>1), the geometrical-optics approximation is applicable to the light scattering phenomenon.

In a case where the light beams extracted from the semiconductor layer 11 have a peak wavelength of approximately 450 nm, the light beams 21 emitted from the active layer 13 and travelling within the semiconductor layer 11 have a wavelength of approximately 188 nm if GaN has a refractive index of 2.4.

The ITO pillars 16 are isolatedly dispersed. Each of the ITO pillars 16 has a size ranging from approximately 100 nm to 500 nm. Hence, α can be estimated to range from approximately 0.5 to 2.6. Accordingly, the light scattering caused by the ITO pillars 16 can be approximated by the Mie scattering that are not dependent on the wavelength of the light.

In addition, ITO has high light transmissibility (of approximately 90% or higher), and provides a favorable ohmic contact with GaN. Hence, the existence of the ITO pillars 16 has little influence on the properties of the semiconductor light-emitting device 10 (i.e., the ITO pillars 6 bring about little increase in light loss caused by light absorption, or little rise in the operational voltage caused by the contact resistance).

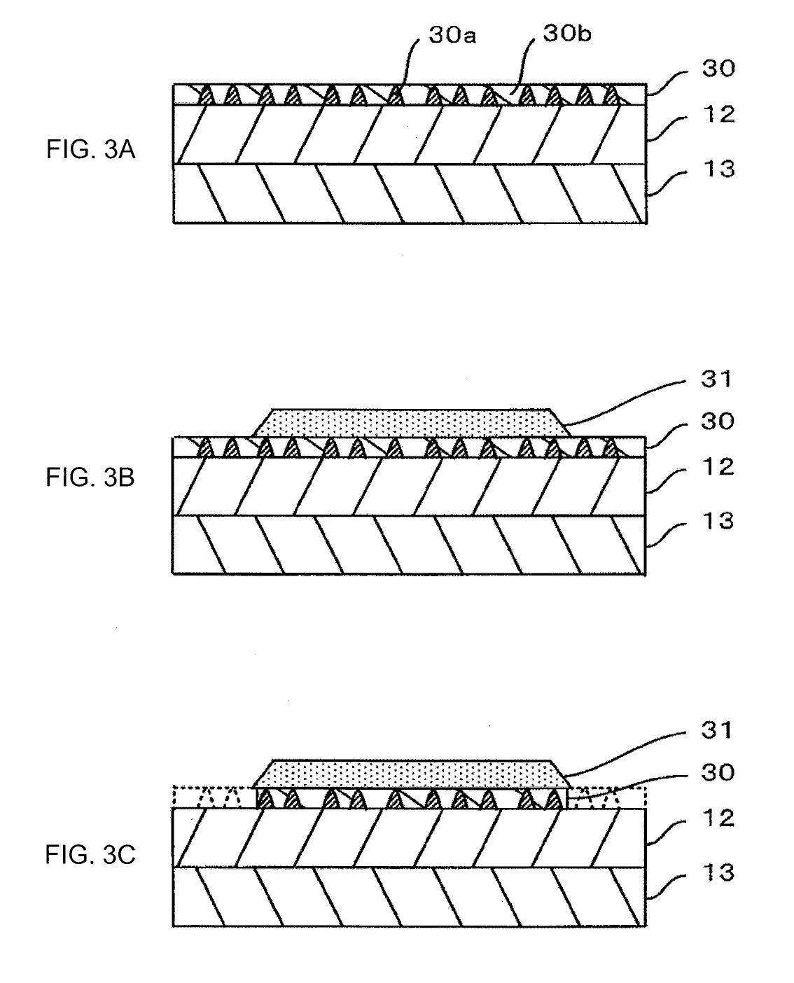

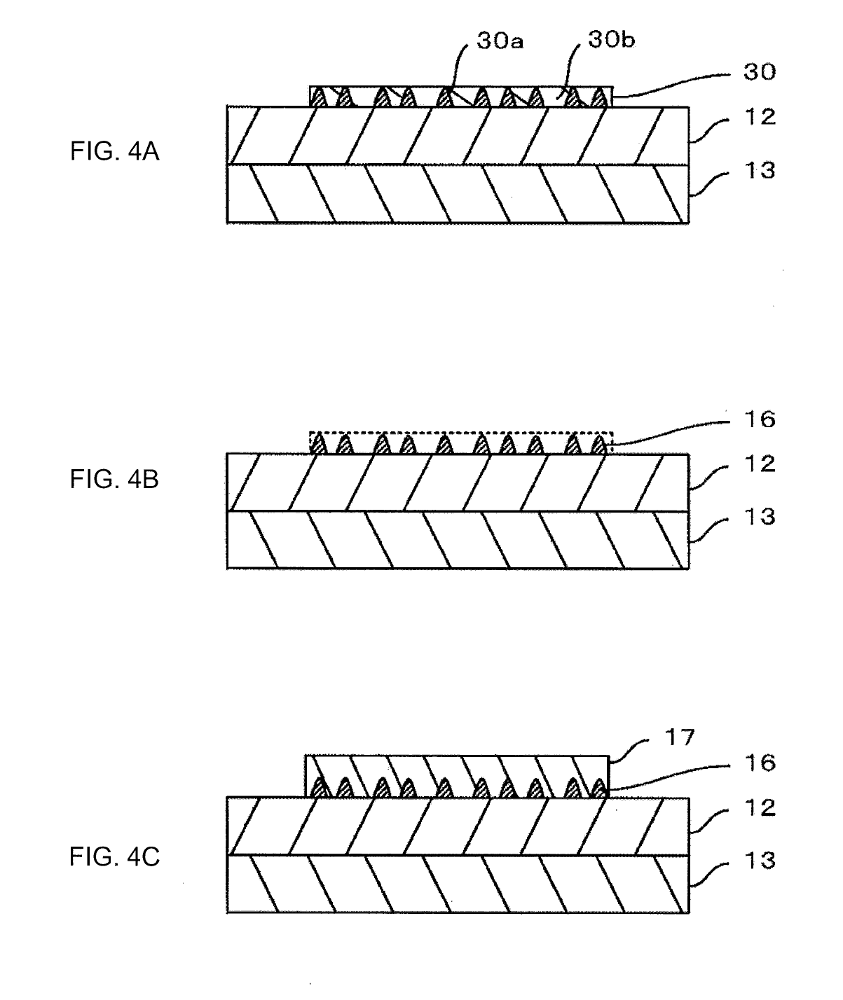

Next, description is given of a method of manufacturing the semiconductor light-emitting device 10. FIGS. 3 and 4 are sectional views sequentially illustrating main portions of steps of manufacturing the semiconductor light-emitting device 10.

First of all, the semiconductor layer 11 is formed by epitaxially growing the n type GaN layer 14, the active layer 13 and the p type GaN layer 12 in this order on a substrate for epitaxial growth, for example, a C-plane sapphire substrate the MOCVD (metal organic chemical vapor deposition) method.

To be more specific, the C-plane sapphire substrate is subjected to a pre-process of, for example, washing with an organic liquid and/or with an acid. Thereafter, the C-plane sapphire substrate is placed in the reaction chamber of the MOCVD apparatus. Then, the temperature of the C-plane sapphire substrate is raised, for example, to 1100° C. by subjecting the C-plane sapphire substrate to high-frequency heating in an ordinary-pressure atmosphere of, for example, a mixed gas containing nitrogen (N2) and hydrogen (H2). Thus, the surface of the substrate is gas-phase etched, so that the films formed on the surfaces by natural oxidation are removed.

Then, the n type GaN layer 14 with a thickness of 3 μm is formed. To this end, a mixed gas of a N2 gas and a H3 gas is used as the carrier gas. An ammonia (NH3) gas and a tri-methyl gallium (TMG) gas, for example, are supplied as the process gases. Furthermore, a silane (SiH4) gas, for example, is supplied as n type dopant.

Subsequently, the n type GaN clad layer with a thickness of 2 μm is formed in a similar manner. Then, the temperature of the substrate is lowered to and kept at a temperature lower than 1100° C., for example 800° C., while continuing supplying the NH3 gas with the supply of the TMG gas and the SiH4 gas stopped.

Then, a GaN barrier layer with a thickness of 5 nm is formed by supplying a N2 gas as a carrier gas, and the NH3 gas and the TMG gas, for example, as the process gases. Furthermore, tri-methyl indium (TMI) is supplied into the GaN barrier layer, so that an InGaN well layer with a thickness of 2.5 nm and with an In composition ratio of 0.1 is formed.

Then, the formation of the GaN barrier layer and the formation of the InGaN well layer are repeated, for example, 7 times by supplying TMI intermittently. Thus, the MQW layer is obtained.

Subsequently, an undoped GaN cap layer with a thickness of 5 nm is formed while continuing supplying the TMG and NH3 gases, and with the supply of the TMI stopped.

Thereafter, the temperature of the substrate is raised to and kept at a temperature higher than 800° C., for example 1030° C., in an atmosphere of a N2 gas while continuing supplying the NH3 gas with the supply of TMG and TMA stopped.

Then, the p type GaN clad layer with a Mg concentration of 1E20 cm-3 and a thickness of approximately 100 nm is formed. To this end, the mixed gas of the N2 gas and the H2 gas is used as the carrier gas. The NH3 gas and the TMG gas are supplied as the process gases. Bis(cyclopentadienyl)magnesium (Cp2Mg) is supplied as the p type dopant.

Subsequently, the p type GaN contact layer 12 with a Mg concentration of 1E21 cm-3 and a thickness of approximately 10 nm is formed by increasing the supply of the Cp2Mg.

Thereafter, the temperature of the substrate is lowered naturally while continuing supplying the NH3 gas with the supply of the TMG stopped and while continuing supplying the carrier gas continuing. The supply of NH3 gas is continued until the temperature of the substrate reaches 500° C. Thus, the semiconductor layer 11 is formed on the sapphire substrate, and the p type GaN layer 12 forms the surface of the semiconductor layer 11.

Then, as FIG. 3A shows, an ITO film 30 with a thickness of approximately 100 nm is formed on the p type GaN layer 12 by, for example, the spattering method. It is generally known that if an ITO film is formed by spattering or the like method, it is possible to obtain the ITO film in which amorphous ITO and crystalline ITO mixedly exist depending on the temperature of the substrate, the plasma concentration, the partial pressure of oxygen, and the like at the time of the film formation.

With regard to the temperature of the substrate, for example, the crystallization temperature of ITO is in a range of 150° C. to 200° C. If the temperature of the substrate is near the crystallization temperature, it is possible to obtain the ITO film in which amorphous ITO and crystalline ITO mixedly exist.

Through cross-sectional TEM (transmission electron microscope) observation and electron-beam diffraction patterns, it is confirmed that crystalline ITO (first ITO) 30a and amorphous ITO (second ITO) 30b mixedly exist in the ITO film 30 in a way that pillar-shaped bodies of the crystalline ITO (first ITO) 30a are dispersed and surrounded by the amorphous ITO 30b.

The etching rate of the crystalline ITO 30a is larger than the etching rate of the amorphous ITO 30b. For example, the etching rate of the crystalline ITO 30a ranges from approximately 50 nm/min to 100 nm/min. For example, the etching rate of the amorphous ITO 30b ranges from approximately 100 nm/min to 500 nm/min. Hence, the selective etching ratio of the crystalline ITO 30a to the amorphous ITO 30b is estimated to range from approximately 2:1 to 5:1.

In this embodiment, the ITO pillars 16 are formed by selectively removing the amorphous ITO 30b with the larger etching rate while leaving the crystalline ITO 30a with the smaller etching rate by use of the difference between the etching rate of the crystalline ITO 30a and that of the amorphous ITO 30b.

Then, as FIG. 3B shows, a resist film 31 is formed in the central portion of the ITO film 30 as a preparation for the patterning of the ITO film 30 into a shape of an electrode.

Subsequently, as FIG. 3C shows, the ITO film 30 is etched by using the resist film 31 as a mask with an etchant of, for example, a mixed acid containing hydrochloric acid and nitric acid. The etching continues until portions of the crystalline ITO 30a and portions of the amorphous ITO 30b are removed from the region uncovered by the mask.

Note that the crystalline ITO 30a is likely to remain as residues. For this reason, it is preferable that the etching be accompanied by the application of ultrasonic waves, or that the etching is followed by ultrasonic washing to physically remove the portions of the crystalline ITO 30a.

Then, as FIG. 4A shows, the resist film 31 is removed, so that the ITO film 30 patterned in the electrode's shape is exposed.

Thereafter, as FIG. 4B shows, the ITO film 30 patterned in the electrode's shape is etched with an etchant of the mixed acid containing hydrochloric acid and nitric acid. This etching, which uses the etching selectivity, continues until the amorphous ITO 30b is removed altogether but portions of the crystalline ITO 30a remains. Thus obtained are the ITO pillars 16.

Then, heat treatment is performed to establish the ohmic contact between the ITO pillars 16 and the p type GaN layer 12. The heat treatment is preferably performed in an atmosphere of a nitrogen gas alone or in an atmosphere of a mixed gas containing both nitrogen and oxygen with a temperature of approximately 400° C. to 750° C. for approximately 1 minute to 20 minutes.

Subsequently, as FIG. 4C shows, a Ag film is vapor-deposited on the p type GaN layer 12 in a manner that the deposited Ag film fills the spaces among the ITO pillars 16 and covers the ITO pillars 16. The reflective electrode 17 is formed by patterning the vapor-deposited Ag film by the photolithography method. It is suitable that the Ag film should have a thickness of 200 nm or more if, for example, each of the ITO pillars 16 have a height of approximately 100 nm. It is desirable that heat treatment should be applied to the Ag electrode in an atmosphere of a mixed gas containing nitrogen and oxygen at a temperature ranging from approximately 300° C. to 500° C. for approximately 1 minute to 10 minutes for the purpose of making the Ag electrode have an ohmic contact with the p type GaN layer 12. The Ag film may have a multi-layer structure including, for example, a AgNi layer, a AgPt layer, and a AgRh layer.

Thereafter, a Ti layer, a Pt layer, and a Au layer are vapor-deposited on the p type GaN layer 12 in a manner that the deposited layers can cover the top surface and the side surfaces of the reflective electrode 17. Thus formed is the first bonding metal layer 18a. Independently of the above-described processes, a silicon substrate is prepared as the support substrate 19, and AuSn is vapor-deposited on the support substrate 19. Thereby formed is the second bonding metal layer 18b.

Then, the first bonding metal layer 18a and the second bonding metal layer 18b are bonded together by thermal compression with the first bonding metal layer 18a and the second bonding metal layer 18b overlapping together. Thereby, the semiconductor layer 11 formed on the sapphire substrate is bonded to the support substrate 19 by means of the bonding metal layer 18, so that a single, unified member can be obtained.

Subsequently, the sapphire substrate is removed by the laser lift-off method or the like. The laser to be used for this purpose is, for example, a KrF laser or a YAG laser. Then, the first electrode 15 is formed on the n type GaN layer 14, and the second electrode 20 is formed on the support substrate 19.

Thereafter, a resist film to be used when the wafer is divided into individual chips is formed, and then the semiconductor layer 11 is etched from above the n type GaN layer 14 while making the resist film retreat until the bonding metal layer 18 is exposed by the RIE (reactive ion etching) method. Thus, the semiconductor layer 11 has the sloping side surfaces such that the distance between the two side surfaces gradually increases from the top of the n type GaN layer 14 towards the bottom of the p type GaN layer 12.

Subsequently, the bonding metal layer 18 and the support substrate 19 are diced with a blade, and thereby obtained is the nitride semiconductor light-emitting device 10 shown in FIG. 1.

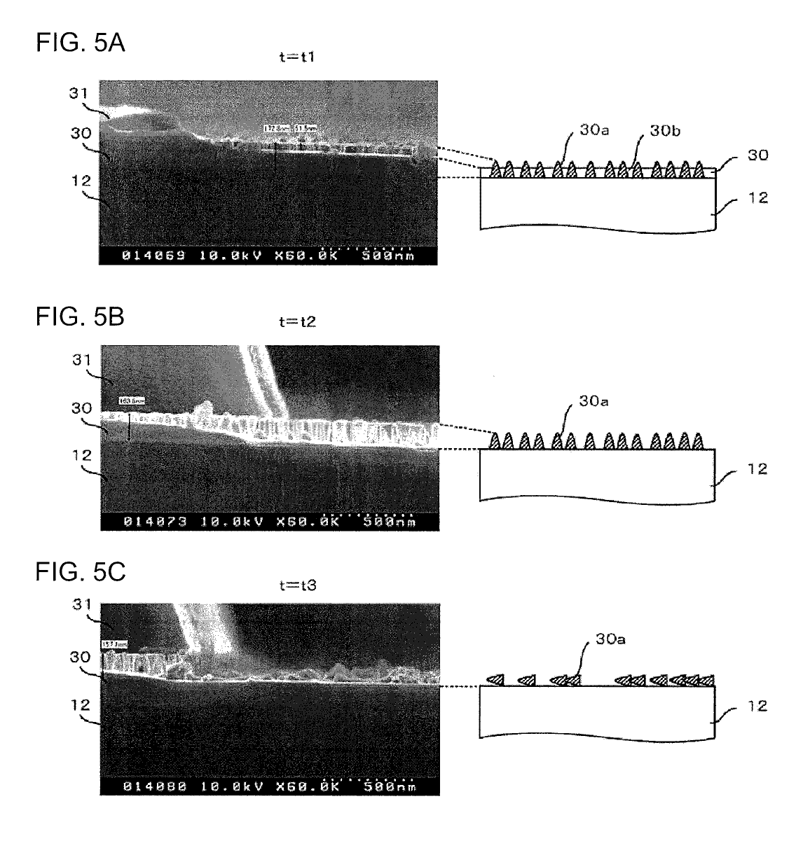

FIGS. 5A to 5C show diagrams illustrating the etching characteristics of the ITO film 30. Each of FIGS. 5A to 5C has a cross-sectional SEM (scanning electron microscope) image showing how the ITO film 30 changes as the etching time passes.

As FIG. 5A shows, a head of the crystalline ITO 30a sticks out of the amorphous ITO 30b after an initial time t1, because the amorphous ITO 30b has been preferentially etched for an initial length of time t1.

As FIG. 5B shows, the amorphous ITO 30b is removed almost completely, but a portion of the crystalline ITO pillars 30a remains on the p type GaN layer 12, after a moderately-long etching time t2. FIG. 5B also shows the state where an etchant is permeating the space between the resist film 31 and the ITO film 30 and thereby the ITO film 30 is side-etched from the end portions.

As FIG. 5C shows, the crystalline ITO 30a is also etched, and the residue of the crystalline ITO 30a is adhered to the surface of the p type GaN layer 12, after an excessively-long etching time t3.

As has been described thus far, in the semiconductor light-emitting device 10 of this embodiment, the ITO pillars 16 are formed dispersedly on the p type GaN layer 12 in a way that portions of the p type GaN layer 12 are exposed. In addition, the reflective electrode 17 is formed in a way that the reflective electrode 17 fills the spaces among the ITO pillars 16 and covers the ITO pillars 16.

Consequently, out of the light beams 21 emitted from the active layer 13, the light beams 22 travelling towards the reflective electrode 17 are stochastically scattered in every direction by the ITO pillars 16. Accordingly, it is possible to increase the proportion of light beams incident on the top and side surfaces of the n type GaN layer 14 at an incidence angle not greater than the critical angle (approximately 24°) for the interface between the GaN surface and the air. Consequently, the semiconductor light-emitting device 10 having the enhanced light extraction efficiency can be obtained.

Note that the light beams that are not scattered by the ITO pillars 16 are reflected regularly by the reflective electrode 17 as in the conventional case. Accordingly, the light beams whose incidence angle on the top and side surfaces of the n type GaN layer 14 is not greater than the critical angle θ can be extracted from the semiconductor layer 11.

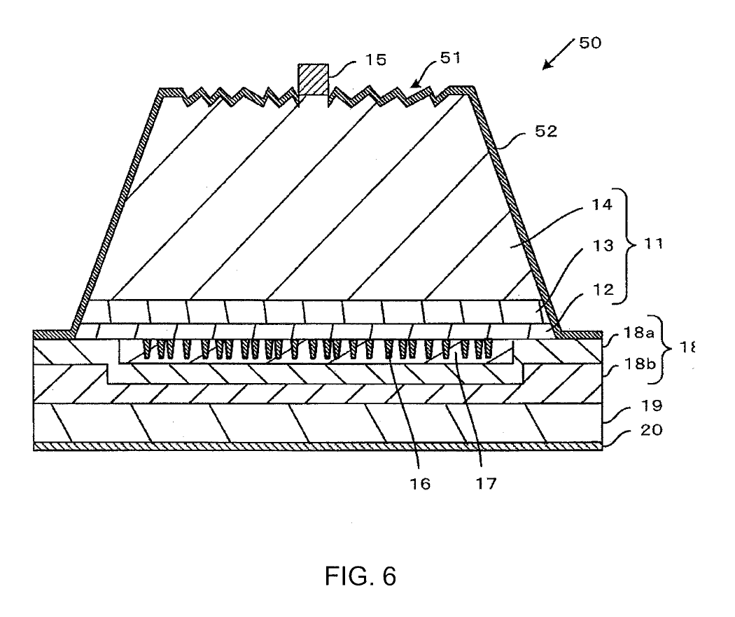

In addition, this embodiment can be carried out in combination with the light-extraction structure formed in the n type GaN layer 14. FIG. 6 is a sectional view illustrating a semiconductor light-emitting device where the light-extraction structure is formed in the n type GaN layer 14.

As FIG. 6 shows, in a semiconductor light-emitting device 50, an asperity portion 51 is formed in the top surface of the n type GaN layer 14. A transparent protection film 52 such as a silicon-oxide film, that is conformal to the irregular-surface portion 51, is formed on the top and side surfaces of the n type GaN layer 14.

The asperity portion 51 is formed by anisotropically etching the sapphire substrate with an etchant of, for example, a molten potassium hydroxide (molten KOH). Alternatively, the asperity portion 51 may be formed by the RIE method with a mask of a resist film patterned in a desired shape. The protection film 52 is formed, for example, by the spattering method at a low temperature.

With use of the asperity portion 51, incident light beams fall incident on the microscopic inclined surfaces of the asperity portion 51 at incidence angles not greater than the critical angle θ with higher probability, and also light beams reflected irregularly by the asperity portion 51 fall incident on the microscopic inclined surfaces of the asperity portion 51 again at incidence angles not greater than the critical angle θ with higher probability. The protection film 52 is formed as a refractive-index reducing layer for increasing an angle at which light beams are extracted from the n type GaN layer 14. Hence, a synergy can be expected from the ITO pillars 16 and the asperity portion 51.

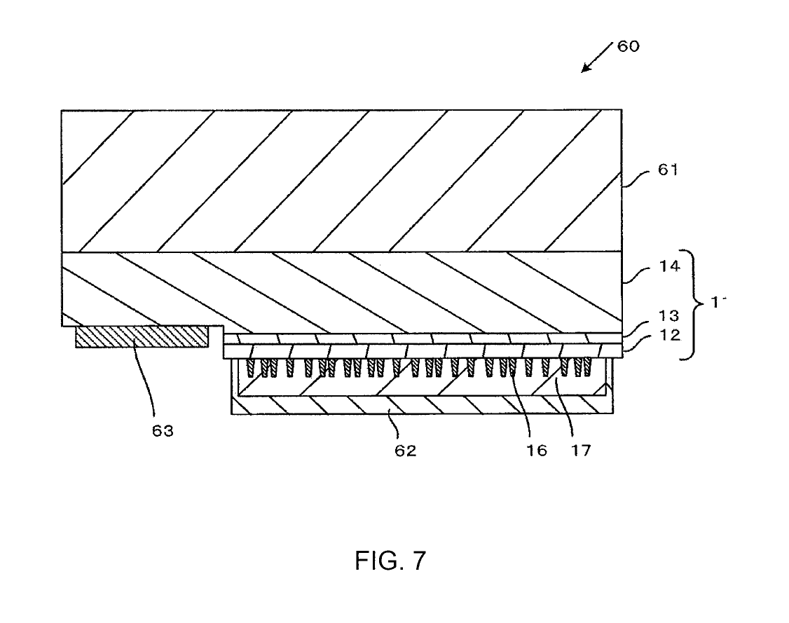

The foregoing descriptions have been provided for the semiconductor light-emitting device 10 of a vertically-conductive type, but the semiconductor light-emitting device 10 may be of a flip-chip type. FIG. 7 is a sectional view illustrating a flip-chip semiconductor light-emitting device.

As FIG. 7 shows, in a semiconductor light-emitting device 60, a light-emitting layer 11 is formed on a transparent substrate 61, for example, a sapphire substrate. A second electrode 62 is formed on the p type GaN layer 12 in a way that the second electrode 62 covers the top and side surfaces of the reflective electrode 17.

In addition, a side of the semiconductor light-emitting device 60 is scooped from the p type GaN layer 12 to a part of the n type GaN layer 14. A first electrode 63 is formed on an exposed portion of the n type GaN layer 14. Then, the type GaN layer 14 concurrently serves as an n type GaN contact layer.

### Second Embodiment

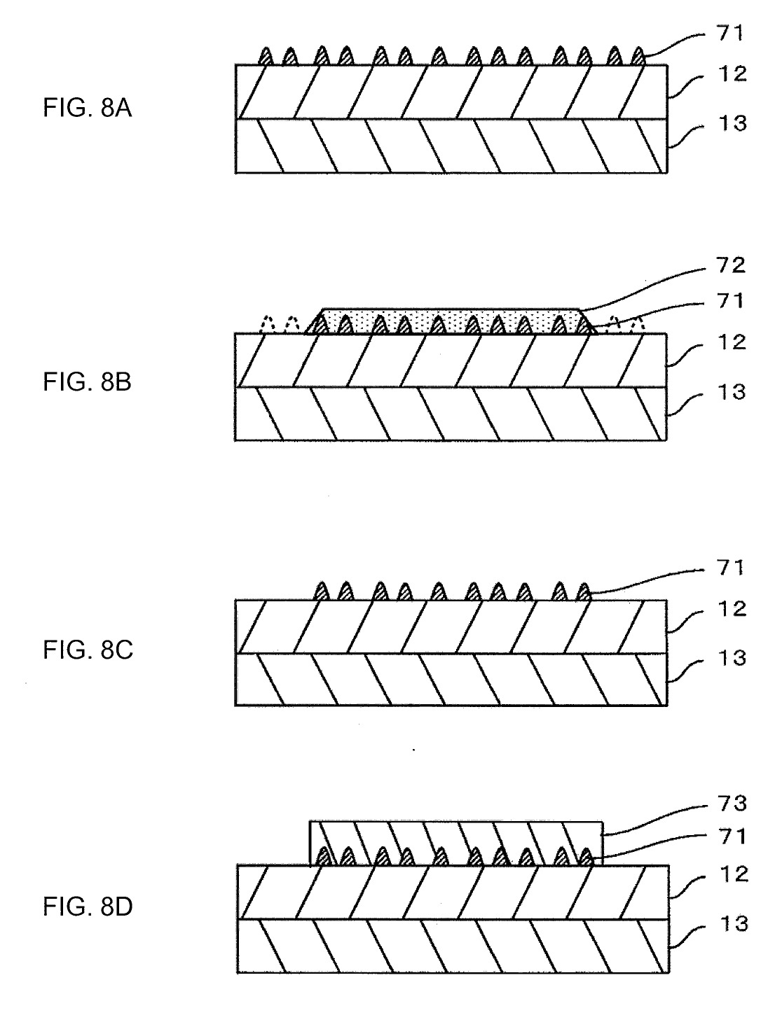

Descriptions will be provided for a semiconductor light-emitting device of Embodiment 2 of the present invention. FIGS. 8A to 8D show sectional views sequentially illustrating main portions of steps for manufacturing a semiconductor light-emitting device of this embodiment. Portions of this embodiment that are identical to their respective counterparts of the Embodiment 1 are denoted by the same reference numerals as are used in Embodiment 1. No description of these portions is given below. Only the points that distinguish this embodiment from Embodiment 1 are to be described below. A difference between this embodiment and Embodiment 1 lies in the direct formation of crystalline ITO pillars on a p type GaN layer.

If the temperature of the substrate is not lower than the crystallization temperature of ITO, the ITO adhered to the substrate generally migrates on the substrate, is agglutinated, and thereby forms granular crystalline ITO in an initial phase. In this embodiment, the granular ITO is used as scattering members. The granular ITO is referred to as the “ITO pillars” in this specification as well.

To be more specific, as FIG. 8A shows, granular ITO pillars 71 are formed on the p type GaN layer 12 by a vapor-deposition method with the substrate being heated at a temperature ranging, for example, from 200° C. to 400° C. The ITO pillars 71 thus obtained have a granular size ranging from 10 nm to 50 nm. If the granular size of the ITO pillars 71 becomes too big, some of the adjacent ITO pillars 71 unite together to form a flat member. Thereby, the ITO pillars 71 lose the light scattering function. Accordingly, the granular size of the ITO pillars 71 is preferably approximately 100 nm or less.

Then, as FIG. 8B shows, a resist film 72 patterned in the shape of an electrode is formed over the ITO pillars 71. Subsequently, by using the resist film 72 as a mask, the ITO pillars 71 are etched with an etchant of a mixed acid containing both hydrochloric acid and nitric acid.

Then, as FIG. 8C shows, the resist film 72 is removed, and thereafter heat treatment is performed to establish the ohmic contact between the ITO pillars 71 and the p type GaN layer 12.

Subsequently, as FIG. 8D shows, a reflective electrode 73 is formed so that the reflective electrode 73 fills the spaces among the ITO pillars 71 and covers the ITO pillars 71. From then onwards, the semiconductor light-emitting device is formed following the processes described in Embodiment 1.

In this embodiment, the size parameter α of the ITO pillars 71 is estimated to range from approximately 0.2 to 0.8. Accordingly, the scattering caused by the ITO pillars 71 can be approximated by using a Mie-scattering as in the case of the ITO pillars 16.

As has been described thus far, in this embodiment, the ITO pillars 71 are formed directly on the p type GaN layer 12. Hence, no etching process to separate the amorphous ITO and crystalline ITO pillars is necessary, so that this embodiment has an advantage that the manufacturing processes as a whole can be simplified.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor light emitting device, comprising:
a semiconductor layer with a multi-layer structure including an active layer, and having a first surface and a second surface opposite to the first surface;
a first electrode formed on the first surface of the semiconductor layer;
a plurality of ITO pillars formed on the second surface of the semiconductor layer, the second surface being exposed partially;
a reflective electrode formed on the second surface of the semiconductor layer, the reflective electrode filling a space between the adjacent ITO pillars and covers the ITO pillars;
a bonding metal layer formed on the reflective electrode; and
a support substrate bonded to the semiconductor layer with the bonding metal layer located in between,
wherein the second surface of the semiconductor layer is exposed from the space between the adjacent ITO pillars, and the reflective electrode is formed on the exposed second surface.

2. A semiconductor light emitting device of claim 1, wherein the ITO pillars are formed by
forming an ITO film on the second surface of the semiconductor layer, the ITO film including: first ITO dispersed and having a first etching rate; and second ITO having a second etching rate greater than the first etching rate, and surrounding the first ITO, and
performing an etching process to remove the second ITO and to leave the first ITO.

3. A semiconductor light emitting device of claim 1 wherein the ITO pillars are formed in an island shape and are arranged dispersedly on the second surface of the semiconductor layer.

4. A semiconductor light emitting device of claim 1, wherein the second surface of the semiconductor layer is made of p type gallium nitride.

5. A semiconductor light emitting device of claim 1, wherein a width of the ITO pillar is about 100 nm to

6. A semiconductor light emitting device of claim 1, wherein each ITO pillars has a width ranging from approximately 100 nm to 500 nm.

7. A semiconductor light emitting device of claim 1, wherein a dense of the plurality of ITO pillars is about 10 to 50 per square micrometer.

8. A semiconductor light emitting device of claim 1, wherein a density of approximately 10 to 50 pillars per square micrometer

9. A semiconductor light emitting device of claim 1, wherein the ITO pillars are formed as shown in FIG. 2.

10. A semiconductor light-emitting device comprising:
a semiconductor layer with a multi-layer structure including an active layer, and having a first surface and a second surface opposite to the first surface;
a plurality of ITO pillars formed on the second surface of the semiconductor layer, the second surface being exposed partially;
a metal layer formed on the second surface of the semiconductor layer, the metal layer filling a space between the adjacent ITO pillars and covers the ITO pillars,
wherein the second surface of the semiconductor layer is exposed from the space between the adjacent ITO pillars, and the metal layer is formed on the exposed second surface.

11. A semiconductor light emitting device of claim 10, wherein the ITO pillars are formed by
forming an ITO film on the second surface of the semiconductor layer, the ITO film including: first ITO dispersed and having a first etching rate; and second ITO having a second etching rate greater than the first etching rate, and surrounding the first ITO, and
performing an etching process to remove the second ITO and to leave the first ITO.

12. A semiconductor light emitting device of claim 10 wherein the ITO pillars are formed in an island shape and are arranged dispersedly on the second surface of the semiconductor layer.

13. A semiconductor light emitting device of claim 10, wherein the second surface of the semiconductor layer is made of p type gallium nitride.

14. A semiconductor light emitting device of claim 10, wherein a width of the ITO pillar is about 100 nm to about 500 nm.

15. A semiconductor light emitting device of claim 10, wherein a dense of the plurality of ITO pillars is about 10 to 50 per square micrometer.

16. A semiconductor light emitting device of claim 10, wherein a density of approximately 10 to 50 pillars per square micrometer

17. A semiconductor light emitting device of claim 10, wherein the ITO pillars are formed as shown in FIG. 2.

18. A semiconductor light emitting device of claim 10, wherein the ITO pillars are isolatedly dispersed.

19. A semiconductor light emitting device of claim 1, wherein the ITO pillars are isolatedly dispersed.

20. A semiconductor light emitting device of claim 10, wherein each ITO pillars has a width ranging from approximately 100 nm to 500 nm.
